(19) United States
(12) Patent Application Publication
(10) Pub. No.: US 2013/0146138 A1
(43) Pub. Date: Jun. 13, 2013

(54) SHAPED ARTICLE HAVING FINE SURFACE IRREGULARITIES AND METHOD FOR PRODUCING THE SHAPED ARTICLE

(71) Applicants: Hitoshi Sekine, Sakura-shi (JP); Yasuhiro Takada, Sakura-shi (JP); Tomoko Shishikura, Sakura-shi (JP); Takayuki Kanematsu, Sakura-shi (JP); Hisashi Tanimoto, Sakura-shi (JP)

(72) Inventors: Hitoshi Sekine, Sakura-shi (JP); Yasuhiro Takada, Sakura-shi (JP); Tomoko Shishikura, Sakura-shi (JP); Takayuki Kanematsu, Sakura-shi (JP); Hisashi Tanimoto, Sakura-shi (JP)

(73) Assignee: DIC CORPORATION, Tokyo (JP)

(21) Appl. No.: 13/702,793

(22) PCT Filed: May 31, 2011
(86) PCT No.: PCT/JP2011/062473

§ 371 Date: Feb. 26, 2013

(30) Foreign Application Priority Data
Jun. 8, 2010 (JP) 2010-130929

(51) Int. Cl. B32B 3/30; H01L 31/048

(52) U.S. Cl. CPC B32B 3/30; H01L 31/048
USPC 136/256; 428/141; 264/293

(57) ABSTRACT

Provided is a shaped article having surface irregularities, including a fine structure including projections and a recess formed between the projections, the fine structure formed by curing a curable resin composition, wherein the curable resin composition contains a composite resin (A) in which a polysiloxane segment (a1) having a structural unit represented by a general formula (1) and/or a general formula (2) and a silanol group and/or a hydrolyzable silyl group is bonded to a vinyl-based polymer segment (a2) having an alcoholic hydroxy group through a bond represented by a general formula (3), and polyisocyanate (B); a content of the polysiloxane segment (a1) with respect to total solids weight of the curable resin composition is 10% to 60% by weight; and a content of the polyisocyanate (B) with respect to total solids weight of the curable resin composition is 5% to 50% by weight.

### TECHNICAL FIELD

The present invention relates to a shaped article having fine surface irregularities.

### BACKGROUND ART

There are known methods in which resin plates and the like are processed so as to have fine irregularities and are used in various applications, for example, as sheets controlling light or matte-surface decorative sheets. For example, the following sheets are known: light-diffusion optical sheets in which desired patterns are printed with ink having a light-diffusion property on transparent bases (for example, refer to Patent Literature 1); and decorative sheets having a low-reflection moth-eye structure in which a nanoimprint mold is pressed into a surface resin layer of a decorative formable sheet so as to form fine irregularities (for example, refer to Patent Literature 2).

Such sheets having fine irregularities have been studied in terms of applications to optical parts such as light guide plates, diffusion plates, nonreflective films, or polarizing films for display apparatuses; and applications to solar-cell devices such as transmissive films for solar-cell devices. In such cases, patterns need to be molded with a high accuracy and the molded fine patterns also need to have sufficient strength to endure subsequent processing and weatherability; in addition, a technique of producing a flat large-area molded article with high productivity is required.

Regarding the technique of producing a flat large-area molded article with high productivity, there is a known method in which a photocurable resin composition is used and fine irregularities are formed by nanoimprinting (for example, refer to Patent Literature 3). Specifically, a photocurable resin composition is used in which the content of at least one monomer containing three or more acrylic groups and/or methacrylic groups in a single molecule such as trimethylolpropane triacrylate is in the range of 20% to 60% by weight, (b) the content of components that turn into solid as a result of bonding due to a photocuring reaction is 98% or more by weight, and (c) the viscosity at 25° C. is 10 mPa·s or less; and a shaped article having fine irregularities formed by nanoimprinting is obtained.

However, when shaped articles formed from the photocurable resin composition are disposed under, for example, harsh conditions for solar cells such as outdoor exposure for a long period of time of 10 or more years, cracking or the like is caused and fine irregularities cannot be maintained, which is problematic.

### CITATION LIST

### Patent Literature

PTL 1: Japanese Unexamined Patent Application Publication No. 2010-91759
PTL 2: Japanese Unexamined Patent Application Publication No. 2010-82829
PTL 3: Japanese Unexamined Patent Application Publication No. 2009-19174

### SUMMARY OF INVENTION

### Technical Problem

An object of the present invention is to provide a shaped article having surface irregularities, the shaped article having a fine structure and excellent long-term outdoor weatherability (specifically, cracking resistance and light resistance).

### Solution to Problem

The inventors of the present invention performed thorough studies and, as a result, have found the following findings. An active-energy-ray-curable resin composition that contains a polysiloxane segment satisfying a specific range and has, in the system, both an alcoholic hydroxy group and an isocyanate group has long-term outdoor weatherability (specifically, cracking resistance and light resistance); in addition, a fine structure can be formed by using a publicly known fine-structure formation method without high-temperature heating. Thus, the above-described object has been achieved.

Specifically, the present invention provides a shaped article having surface irregularities, including a fine structure including projections and a recess formed between the projections, the fine structure being formed in part of or in entirety of a surface of the molded article formed by curing a curable resin composition,

wherein the curable resin composition contains a composite resin (A) in which a polysiloxane segment (a1) having a structural unit represented by a general formula (1) and/or a general formula (2) and a silanol group and/or a hydrolyzable silyl group is bonded to a vinyl-based polymer segment (a2) having an alcoholic hydroxy group through a bond represented by a general formula (3), and polyisocyanate (B); a content of the polysiloxane segment (a1) with respect to total solids weight of the curable resin composition is 10% to 60% by weight; and a content of the polyisocyanate (B) with respect to total solids weight of the curable resin composition is 5% to 50% by weight

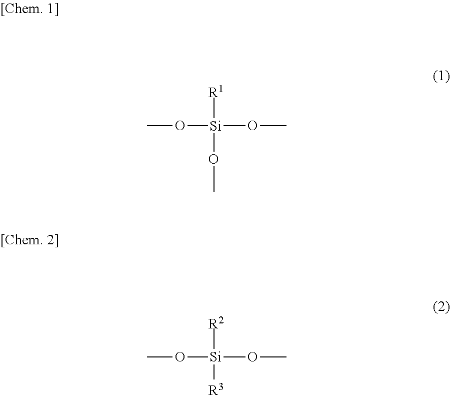

(in the general formulae (1) and (2), R¹, R², and R³ each independently represent a group having one polymerizable double bond and selected from the group consisting of —R⁴—CH═CH₂, —R⁴—C(CH₃)═CH₂, —R⁴—O—CO—C(CH₃)═CH₂, and —R⁴—O—CO—CH═CH₂ (where R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms; at least one of R¹, R², and R³ represents the group having a polymerizable double bond)

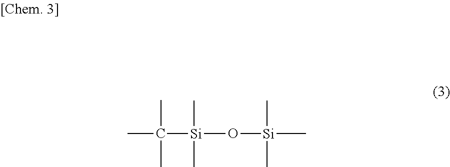

(in the general formula (3), the carbon atom constitutes a part of the vinyl-based polymer segment (a2), and the silicon atom that is bonded to the oxygen atom only constitutes a part of the polysiloxane segment (a1)).

The present invention also provides a method for producing the above-described shaped article having surface irregularities, the method including pressing a mold having an irregular structure into a curable-resin-composition layer disposed on a surface of a base; in this state, curing the curable-resin-composition layer by an active energy ray applied on a resin-composition side; and subsequently releasing the mold.

The present invention also provides a surface protective member for a light-receiving surface of a solar-cell module, including the above-described shaped article having surface irregularities; and a solar-cell module including the surface protective member for a light-receiving surface.

### Advantageous Effects of Invention

The present invention can provide a shaped article having surface irregularities, the shaped article having a fine structure and long-term outdoor weatherability (specifically, cracking resistance and light resistance).

### BRIEF DESCRIPTION OF DRAWING

FIG. 1 illustrates a solar-cell module.

### DESCRIPTION OF EMBODIMENTS

### (Curable Resin Composition: Composite Resin (A))

In a composite resin (A) used in the present invention, a polysiloxane segment (a1) having a structural unit represented by the general formula (1) and/or the general formula (2) and a silanol group and/or a hydrolyzable silyl group (hereafter simply referred to as the polysiloxane segment (a1)) is bonded to a vinyl-based polymer segment (a2) having an alcoholic hydroxy group (hereafter simply referred to as the vinyl-based polymer segment (a2)) through a bond represented by the general formula (3). The bond represented by the general formula (3) provides a shaped article having particularly high alkaline resistance, which is preferred.

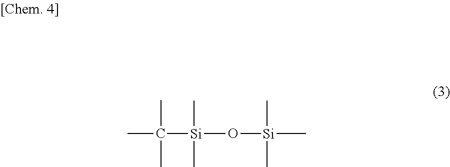

The bond represented by the general formula (3) is formed by a dehydration condensation reaction between a silanol group and/or a hydrolyzable silyl group of the polysiloxane segment (a1) described below and a silanol group and/or a hydrolyzable silyl group of the vinyl-based polymer segment (a2) described below. Accordingly, in the general formula (3), the carbon atom constitutes a part of the vinyl-based polymer segment (a2), and the silicon atom that is bonded to the oxygen atom only constitutes a part of the polysiloxane segment (a1).

As to the structure of the composite resin (A), for example, the composite resin (A) may be a composite resin having a graft structure in which the polysiloxane segment (a1) is chemically bonded as a side chain of the polymer segment (a2), or a composite resin having a block structure in which the polymer segment (a2) and the polysiloxane segment (a1) are chemically bonded.

(Polysiloxane Segment (a1))

The polysiloxane segment (a1) according to the present invention has a structural unit represented by the general formula (1) and/or the general formula (2) and a silanol group and/or a hydrolyzable silyl group. The structural unit represented by the general formula (1) and/or the general formula (2) includes a group having a polymerizable double bond.

(Structural Unit Represented by General Formula (1) and/or General Formula (2))

The structural unit represented by the general formula (1) and/or the general formula (2) has, as an essential component, a group having a polymerizable double bond.

Specifically, in the general formulae (1) and (2), R¹, R², and R³ each independently represent a group having one polymerizable double bond and selected from the group consisting of —R⁴—CH═CH₂, —R⁴—C(CH₃)═CH₂, —R⁴—O—CO—C(CH₃)═CH₂, and —R⁴—O—CO—CH═CH₂ (where R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms; at least one of R¹, R², and R³ represents the group having a polymerizable double bond. Examples of the alkylene group having 1 to 6 carbon atoms in R⁴ include a methylene group, an ethylene group, a propylene group, an isopropylene group, a butylene group, an isobutylene group, a sec-butylene group, a tert-butylene group, a pentylene group, an isopentylene group, a neopentylene group, a tert-pentylene group, a 1-methylbutylene group, a 2-methylbutylene group, a 1,2-dimethylpropylene group, a 1-ethylpropylene group, a hexylene group, an isohexylene group, a 1-methylpentylene group, a 2-methylpentylene group, a 3-methylpentylene group, a 1,1-dimethylbutylene group, a 1,2-dimethylbutylene group, a 2,2-dimethylbutylene group, a 1-ethylbutylene group, a 1,1,2-trimethylpropylene group, a 1,2,2-trimethylpropylene group, a 1-ethyl-2-methylpropylene group, and a 1-ethyl-1-methylpropylene group. In particular, in view of ease of availability of the raw material, R⁴ preferably represents a single bond or an alkylene group having 2 to 4 carbon atoms.

Examples of the alkyl group having 1 to 6 carbon atoms include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group.

Examples of the cycloalkyl group having 3 to 8 carbon atoms include a cyclopropyl group, a cyclobutyl group, a cyclopentyl group, and a cyclohexyl group. Examples of the aryl group include a phenyl group, a naphthyl group, a 2-methylphenyl group, a 3-methylphenyl group, a 4-methylphenyl group, a 4-vinylphenyl group, and a 3-isopropylphenyl group.

Examples of the aralkyl group having 7 to 12 carbon atoms include a benzyl group, a diphenylmethyl group, and a naphthylmethyl group.

At least one of R¹, R², and R³ represents the group having a polymerizable double bond. Specifically, when the polysiloxane segment (a1) has a structural unit represented by the general formula (1) only, R¹ represents the group having a polymerizable double bond. When the polysiloxane segment (a1) has a structural unit represented by the general formula (2) only, R² and/or R³ represents the group having a polymerizable double bond. When the polysiloxane segment (a1) has structural units represented by the general formula (1) and the general formula (2), at least one of R¹, R², and R³ represents the group having a polymerizable double bond.

In the present invention, the number of the polymerizable double bond in the polysiloxane segment (a1) is preferably 2 or more, more preferably 3 to 200, still more preferably 3 to 50, resulting in a shaped article having high scratch resistance. Specifically, when the content of the polymerizable double bond in the polysiloxane segment (a1) is 3% to 20% by weight, desired scratch resistance can be achieved.

Note that the content of the polymerizable double bond is calculated here such that the molecular weight in a group having —CH═CH₂ is regarded as 27 and the molecular weight in a group having —C(CH₃)═CH₂ is regarded as 41.

The structural unit represented by the general formula (1) and/or the general formula (2) is a three-dimensional network polysiloxane structural unit in which two or three bonds of silicon contribute to crosslinking. Although the three-dimensional network structure is formed, a dense network structure is not formed. Accordingly, for example, gelation is not caused during production and the resultant composite resin has high long-term storage stability.

(Silanol Group and/or Hydrolyzable Silyl Group)

In the present invention, the silanol group is a silicon-containing group having a hydroxy group directly bonded to the silicon atom. Specifically, the silanol group is preferably a silanol group formed by bonding between a hydrogen atom and an oxygen atom that has a dangling bond in the structural unit represented by the general formula (1) and/or the general formula (2).

In the present invention, the hydrolyzable silyl group is a silicon-containing group having a hydrolyzable group directly bonded to the silicon atom. Specifically, an example is a group represented by a general formula (4).

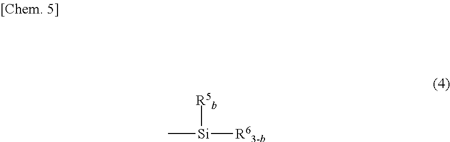

(In the general formula (4), R⁵ represents a monovalent organic group such as an alkyl group, an aryl group, or an aralkyl group; R⁶ represents a hydrolyzable group selected from the group consisting of a halogen atom, an alkoxy group, an acyloxy group, a phenoxy group, an aryloxy group, a mercapto group, an amino group, an amido group, an aminooxy group, an iminooxy group, and an alkenyloxy group; and b represents an integer of 0 to 2.)

As to R⁵, examples of the alkyl group include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group.

Examples of the aryl group include a phenyl group, a naphthyl group, a 2-methylphenyl group, a 3-methylphenyl group, a 4-methylphenyl group, a 4-vinylphenyl group, and a 3-isopropylphenyl group.

Examples of the aralkyl group include a benzyl group, a diphenylmethyl group, and a naphthylmethyl group.

As to R⁶, examples of the halogen atom include a fluorine atom, a chlorine atom, a bromine atom, and an iodine atom.

Examples of the alkoxy group include a methoxy group, an ethoxy group, a propoxy group, an isopropoxy group, a butoxy group, a sec-butoxy group, and a tert-butoxy group.

Examples of the acyloxy group include formyloxy, acetoxy, propanoyloxy, butanoyloxy, pivaloyloxy, pentanoyloxy, phenylacetoxy, acetoacetoxy, benzoyloxy, and naphthoyloxy.

Examples of the aryloxy group include phenyloxy and naphthyloxy.

Examples of the alkenyloxy group include a vinyloxy group, an allyoxy group, a 1-propenyloxy group, an isopropenyloxy group, a 2-butenyloxy group, a 3-butenyloxy group, a 2-pentenyloxy group, a 3-methyl-3-butenyloxy group, and a 2-hexenyloxy group.

As a result of hydrolysis of the hydrolyzable group represented by R⁶, the hydrolyzable silyl group represented by the general formula (4) turns into a silanol group. In particular, R⁶ preferably represents a methoxy group or an ethoxy group because these groups have high hydrolyzability.

Specifically, as to the hydrolyzable silyl group, an oxygen atom having a dangling bond in the structural unit represented by the general formula (1) and/or the general formula (2) is preferably bonded to or substituted by the hydrolyzable group.

As to the silanol group and the hydrolyzable silyl group, during curing caused by an active energy ray, while the active-energy-ray curing reaction proceeds, a hydrolytic condensation reaction also proceeds between the hydroxy groups of the silanol groups and the hydrolyzable groups of the hydrolyzable silyl groups. Accordingly, the crosslinking density of the polysiloxane structure increases and a shaped article excellent in terms of solvent resistance or the like can be formed.

The silanol group or the hydrolyzable silyl group is used for bonding the polysiloxane segment (a1) having the silanol group or the hydrolyzable silyl group to the vinyl based polymer segment (a2) having an alcoholic hydroxy group described below through a bond represented by the general formula (3).

The polysiloxane segment (a1) has a structural unit represented by the general formula (1) and/or the general formula (2) and a silanol group and/or a hydrolyzable silyl group. The polysiloxane segment (a1) is not particularly limited further and may include another group. For example,

the polysiloxane segment (a1) may include a structural unit in which R¹ in the general formula (1) represents the group having a polymerizable double bond, and a structural unit in which R¹ in the general formula (1) represents an alkyl group such as methyl;

the polysiloxane segment (a1) may include a structural unit in which R¹ in the general formula (1) represents the group having a polymerizable double bond, a structural unit in which R¹ in the general formula (1) represents an alkyl group such as methyl, and a structural unit in which R² and R³ in the general formula (2) represent an alkyl group such as methyl; or

the polysiloxane segment (a1) may include a structural unit in which R¹ in the general formula (1) represents the group having a polymerizable double bond, and a structural unit in which R² and R³ in the general formula (2) represent an alkyl group such as methyl. Thus, the polysiloxane segment (a1) is not particularly limited.

Specific examples of the structure of the polysiloxane segment (a1) are as follows.

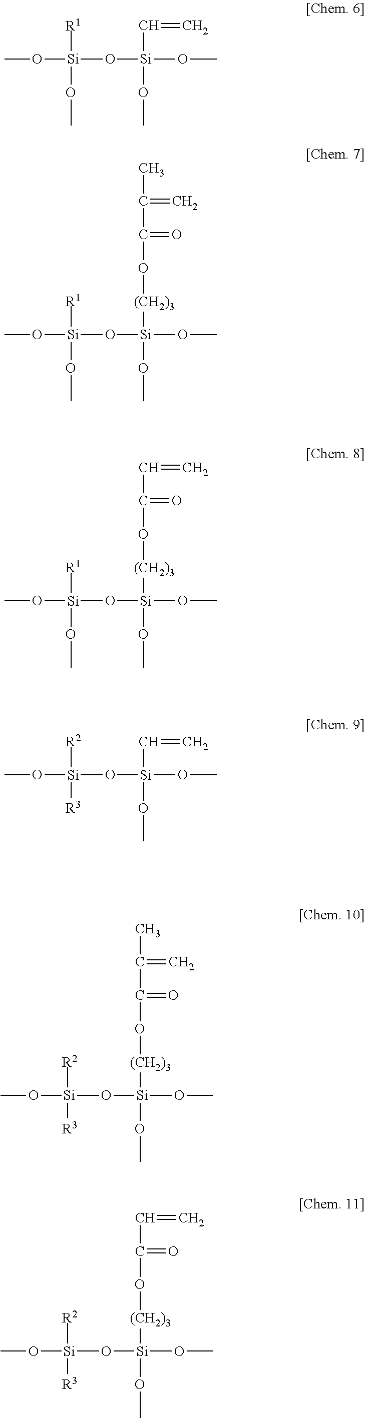

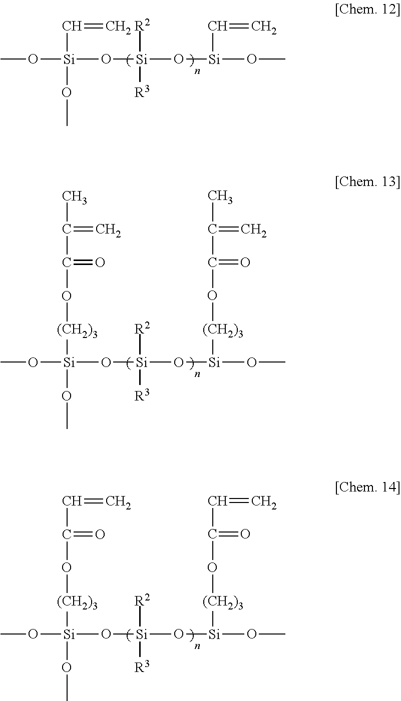

In the present invention, the content of the polysiloxane segment (a1) with respect to the total solids weight of the curable resin composition is 10% to 60% by weight. Thus, high weatherability is achieved.

(Vinyl-Based Polymer Segment (a2) Having Alcoholic Hydroxy Group)

In the present invention, the vinyl-based polymer segment (a2) is a vinyl polymer segment such as an acrylic polymer, a fluoroolefin polymer, a vinylester polymer, an aromatic vinyl polymer, or a polyolefin polymer, each of which has an alcoholic hydroxy group. In particular, an acrylic-based polymer segment synthesized by copolymerizing a (meth)acrylic monomer having an alcoholic hydroxy group is preferred because the resultant shaped article has high transparency and high glossiness.

Specific examples of the (meth)acrylic monomer having an alcoholic hydroxy group include hydroxyalkyl esters of various α,β-ethylenically unsaturated carboxylic acid such as 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, 3-chloro-2-hydroxypropyl (meth)acrylate, di-2-hydroxyethyl fumarate, mono-2-hydroxyethyl monobutyl fumarate, polyethylene glycol mono(meth)acrylate, polypropylene glycol mono(meth)acrylate, and “PLACCEL FM and PLACCEL FA” [caprolactone adduct monomers, manufactured by DAICEL CHEMICAL INDUSTRIES, LTD.]; and ε-caprolactone adducts of the foregoing.

In particular, 2-hydroxyethyl (meth)acrylate is preferred because of ease of reaction.

Since the content of the polyisocyanate (B) described below with respect to the total solids weight of the curable resin composition is 5% to 50% by weight, the amount of the alcoholic hydroxy group is preferably appropriately determined by calculation from the amount of the polyisocyanate (B) actually added.

As described below, in the present invention, more preferably, an active-energy-ray-curable monomer having an alcoholic hydroxy group is additionally used. Accordingly, the amount of the alcoholic hydroxy group in the vinyl-based polymer segment (a2) having an alcoholic hydroxy group can be determined further in consideration of the amount of the additionally used active-energy-ray-curable monomer having an alcoholic hydroxy group. Practically, the alcoholic hydroxy group is preferably contained such that the hydroxyl value in terms of the vinyl-based polymer segment (a2) is in the range of 30 to 300.

Another copolymerizable (meth)acrylic monomer is not particularly limited and publicly known monomers may be used. Vinyl monomers may also be copolymerized. Examples include alkyl (meth)acrylates having an alkyl group having 1 to 22 carbon atoms such as methyl (meth)acrylate, ethyl (meth)acrylate, n-propyl (meth)acrylate, n-butyl (meth)acrylate, isobutyl (meth)acrylate, tert-butyl (meth)acrylate, 2-ethylhexyl (meth)acrylate, and lauryl (meth)acrylate; aralkyl (meth)acrylates such as benzyl (meth)acrylate and 2-phenylethyl (meth)acrylate; cycloalkyl (meth)acrylates such as cyclohexyl (meth)acrylate and isobornyl (meth)acrylate; m-alkoxyalkyl (meth)acrylates such as 2-methoxyethyl (meth)acrylate and 4-methoxybutyl (meth)acrylate; aromatic vinyl-based monomers such as styrene, p-tert-butyl styrene, α-methyl styrene, and vinyltoluene; carboxylic acid vinyl esters such as vinyl acetate, vinyl propionate, vinyl pivalate, and vinyl benzoate; crotonic acid alkyl esters such as methyl crotonate and ethyl crotonate; unsaturated dibasic acid dialkyl esters such as dimethyl maleate, di-n-butyl maleate, dimethyl fumarate, and dimethyl itaconate; α-olefins such as ethylene and propylene; fluoroolefins such as vinylidene fluoride, tetrafluoroethylene, hexafluoropropylene, and chlorotrifluoroethylene; alkyl vinyl ethers such as ethyl vinyl ether and n-butyl vinyl ether; cycloalkyl vinyl ethers such as cyclopentyl vinyl ether and cyclohexyl vinyl ether; and tert-amido-group-containing monomers such as N,N-dimethyl (meth)acrylamide, N-(meth)acryloylmorpholine, N-(meth)acryloylpyrrolidine, and N-vinylpyrrolidone.

In copolymerization of such monomers, the polymerization method, the solvent, and the polymerization initiator are also not particularly limited. The vinyl-based polymer segment (a2) can be obtained by a publicly known method. For example, the vinyl-based polymer segment (a2) can be obtained by various polymerization methods such as a bulk radical polymerization method, a solution radical polymerization method, and a non-aqueous dispersion radical polymerization method and by using polymerization initiators such as 2,2′-azobis(isobutyronitrile), 2,2′-azobis(2,4-dimethylvaleronitrile), 2,2′-azobis(2-methylbutyronitrile), tert-butylperoxy pivalate, tert-butylperoxy benzoate, tert-butylperoxy-2-ethyl hexanoate, di-tert-butyl peroxide, cumene hydroperoxide, and diisopropyl peroxycarbonate.

The vinyl-based polymer segment (a2) preferably has a number-average molecular weight (hereafter abbreviated as Mn) in the range of 500 to 200,000. In such a case, thickening or gelation in the production of the composite resin (A) can be suppressed and the resultant shaped article has high durability. In particular, Mn is more preferably in the range of 700 to 100,000, still more preferably in the range of 1,000 to 50,000.

The vinyl-based polymer segment (a2) is bonded to the polysiloxane segment (a1) through the bond represented by the general formula (3) to form the composite resin (A). For this reason, the vinyl-based polymer segment (a2) has a silanol group and/or a hydrolyzable silyl group directly bonded to a carbon atom therein. Such a silanol group and/or a hydrolyzable silyl group turns into the bond represented by the general formula (3) in the production of the composite resin (A) described below and hence is not substantially present in the vinyl-based polymer segment (a2) of the composite resin (A), which is a final product. However, remaining of a silanol group and/or a hydrolyzable silyl group in the vinyl-based polymer segment (a2) does not cause any problems. During curing caused by an active energy ray, while the active-energy-ray curing reaction proceeds, a hydrolytic condensation reaction also proceeds between the hydroxy groups of the silanol groups and the hydrolyzable groups of the hydrolyzable silyl groups. Accordingly, the crosslinking density of the polysiloxane structure increases and a shaped article excellent in terms of solvent resistance or the like can be formed.

The vinyl-based polymer segment (a2) having a silanol group and/or a hydrolyzable silyl group directly bonded to a carbon atom is specifically obtained by copolymerizing the (meth)acrylic monomer having an alcoholic hydroxy group, the commonly used monomer, and a vinyl-based monomer having a silanol group and/or a hydrolyzable silyl group directly bonded to a carbon atom.

Examples of the vinyl-based monomer having a silanol group and/or a hydrolyzable silyl group directly bonded to a carbon atom include vinyltrimethoxysilane, vinyltriethoxysilane, vinylmethyldimethoxysilane, vinyltri(2-methoxyethoxy)silane, vinyltriacetoxysilane, vinyltrichlorosilane, 2-trimethoxysilylethyl vinyl ether, 3-(meth)acryloyloxypropyltrimethoxysilane, 3-(meth)acryloyloxypropyltriethoxysilane, 3-(meth)acryloyloxypropylmethyldimethoxysilane, and 3-(meth)acryloyloxypropyltrichlorosilane. In particular, vinyltrimethoxysilane and 3-(meth)acryloyloxypropyltrimethoxysilane are preferred because a hydrolysis reaction can easily proceed and, after the reaction, byproducts can be easily removed.

### (Method for Producing Composite Resin (A))

The composite resin (A) used in the present invention can be specifically produced by methods described in the following (First method) to (Third method).

(First Method)

The (meth)acrylic monomer having an alcoholic hydroxy group, the commonly used (meth)acrylic monomer or the like, and the vinyl-based monomer having a silanol group and/or a hydrolyzable silyl group directly bonded to a carbon atom are copolymerized to provide the vinyl-based polymer segment (a2) having a silanol group and/or a hydrolyzable silyl group directly bonded to a carbon atom. This is mixed with a silane compound having a silanol group and/or a hydrolyzable silyl group and a polymerizable double bond and optionally with a commonly used silane compound; and a hydrolytic condensation reaction is caused.

In this method, a silanol group or a hydrolyzable silyl group of the silane compound having a silanol group and/or a hydrolyzable silyl group and a polymerizable double bond and a silanol group and/or a hydrolyzable silyl group of the vinyl-based polymer segment (a2) having a silanol group and/or a hydrolyzable silyl group directly bonded to a carbon atom undergo a hydrolytic condensation reaction. As a result, the polysiloxane segment (a1) is formed and the composite resin (A) in which the polysiloxane segment (a1) and the vinyl-based polymer segment (a2) having an alcoholic hydroxy group are combined through the bond represented by the general formula (3) is obtained.

(Second Method)

As in the First method, the vinyl-based polymer segment (a2) having a silanol group and/or a hydrolyzable silyl group directly bonded to a carbon atom is obtained.

On the other hand, a silane compound having a silanol group and/or a hydrolyzable silyl group and a polymerizable double bond and optionally a commonly used silane compound undergo a hydrolytic condensation reaction to provide the polysiloxane segment (a1). A silanol group and/or a hydrolyzable silyl group of the vinyl-based polymer segment (a2) and a silanol group and/or a hydrolyzable silyl group of the polysiloxane segment (a1) undergo a hydrolytic condensation reaction.

(Third Method)

As in the First method, the vinyl-based polymer segment (a2) having a silanol group and/or a hydrolyzable silyl group directly bonded to a carbon atom is obtained. On the other hand, as in the Second method, the polysiloxane segment (a1) is obtained. Furthermore, mixing with a silane compound containing a silane compound having a polymerizable double bond and optionally a commonly used silane compound is performed; and a hydrolytic condensation reaction is caused.

Specific examples of the silane compound having a silanol group and/or a hydrolyzable silyl group and a polymerizable double bond in the (First method) to (Third method) include vinyltrimethoxysilane, vinyltriethoxysilane, vinylmethyldimethoxysilane, vinyltri(2-methoxyethoxy)silane, vinyltriacetoxysilane, vinyltrichlorosilane, 2-trimethoxysilylethyl vinyl ether, 3-(meth)acryloyloxypropyltrimethoxysilane, 3-(meth)acryloyloxypropyltriethoxysilane, 3-(meth)acryloyloxypropylmethyldimethoxysilane, and 3-(meth)acryloyloxypropyltrichlorosilane. In particular, vinyltrimethoxysilane and 3-(meth)acryloyloxypropyltrimethoxysilane are preferred because a hydrolysis reaction can easily proceed and, after the reaction, byproducts can be easily removed.

Examples of the commonly used silane compound used in the (First method) to (Third method) include various organotrialkoxysilanes such as methyltrimethoxysilane, methyltriethoxysilane, methyltri-n-butoxysilane, ethyltrimethoxysilane, n-propyltrimethoxysilane, iso-butyltrimethoxysilane, cyclohexyltrimethoxysilane, phenyltrimethoxysilane, and phenyltriethoxysilane; various diorganodialkoxysilanes such as dimethyldimethoxysilane, dimethyldiethoxysilane, dimethyldi-n-butoxysilane, diethyldimethoxysilane, diphenyldimethoxysilane, methylcyclohexyldimethoxysilane, and methylphenyldimethoxysilane; and chlorosilanes such as methyltrichlorosilane, ethyltrichlorosilane, phenyltrichlorosilane, vinyltrichlorosilane, dimethyldichlorosilane, diethyldichlorosilane, and diphenyldichlorosilane. In particular, preferred are organotrialkoxysilanes and diorganodialkoxysilanes in which a hydrolysis reaction can easily proceed and, after the reaction, byproducts can be easily removed.

A tetraalkoxysilane compound such as tetramethoxysilane, tetraethoxysilane, or tetra-n-propoxysilane or a partial hydrolytic condensation product, of the tetraalkoxysilane compound may be additionally used as long as advantages of the present invention are not degraded. When the tetraalkoxysilane compound or a partial hydrolytic condensation product thereof is additionally used, the content of the silicon atom of the tetraalkoxysilane compound with respect to the total silicon atoms of the polysiloxane segment (a1) is preferably not more than 20 mol %.

The silane compound may be used in combination with a metal alkoxide compound in which the metal is other than a silicon atom such as boron, titanium, zirconium, or aluminum as long as advantages of the present invention are not degraded. For example, the metal alkoxide compound is preferably used such that the content of the metal atom of the metal alkoxide compound with respect to the total silicon atoms of the polysiloxane segment (a1) is not more than 25 mol %.

The hydrolytic condensation reaction in the (First method) to (Third method) means that some of the hydrolyzable groups are hydrolyzed under the influence of water or the like to form hydroxy groups and a condensation reaction subsequently proceeds between the hydroxy groups or between the hydroxy groups and the hydrolyzable groups. Although the hydrolytic condensation reaction can be caused to proceed by a publicly known method, a method of causing the reaction to proceed by feeding water and a catalyst in the production step is simple and preferred.

Examples of the catalyst used include inorganic acids such as hydrochloric acid, sulfuric acid, and phosphoric acid; organic acids such as p-toluenesulfonic acid, monoisopropyl phosphate, and acetic acid; inorganic bases such as sodium hydroxide and potassium hydroxide; titanates such as tetraisopropyl titanate and tetrabutyl titanate; various compounds containing a basic nitrogen atom such as 1,8-diazabicyclo[5.4.0]undecene-7 (DBU), 1,5-diazabicyclo[4.3.0]nonene-5 (DBN), 1,4-diazabicyclo[2.2.2]octane (DABCO), tri-n-butylamine, dimethylbenzylamine, monoethanolamine, imidazole, and 1-methylimidazole; various quaternary ammonium salts such as a tetramethylammonium salt, a tetrabutylammonium salt, and a dilauryldimethylammonium salt, having, as counter anions such as chloride, bromide, carboxylate, and hydroxide; and tin carboxylates such as dibutyltin diacetate, dibutyltin dioctoate, dibutyltin dilaurate, dibutyltin diacetylacetonate, tin octylate, and tin stearate. The catalyst may be used alone or in combination of two or more thereof.

The amount of the catalyst added is not particularly limited. In general, the content of the catalyst with respect to the total weight of the compounds having a silanol group or a hydrolyzable silyl group is preferably in the range of 0.0001% to 10% by weight, more preferably in the range of 0.0005% to 3% by weight, and particularly preferably in the range of 0.001% to 1% by weight.

The amount of water fed with respect to 1 mol of a silanol group or a hydrolyzable silyl group of the compounds having a silanol group or a hydrolyzable silyl group is preferably 0.05 mol or more, more preferably 0.1 mol or more, particularly preferably 0.5 mol or more.

The catalyst and water may be collectively or successively fed. The catalyst and water having been mixed in advance may be fed.

The reaction temperature for the hydrolytic condensation reaction in the (First method) to (Third method) is suitably in the range of 0° C. to 150° C., preferably in the range of 20° C. to 100° C. As to the pressure, the reaction can be performed under any conditions of normal pressure, increased pressure, and reduced pressure. If necessary, alcohol and water that can be generated as byproducts in the hydrolytic condensation reaction may be removed by a process such as distillation.

The proportions of the compounds charged in the (First method) to (Third method) are appropriately selected in accordance with a desired structure of the composite resin (A) used in the present invention. In particular, the composite resin (A) is preferably produced such that the content of the polysiloxane segment (a1) is 30% to 80% by weight, more preferably 30% to 75% by weight, because the resultant shaped article has high durability.

In the (First method) to (Third method), a specific method of combining, in blocks, the polysiloxane segment and the vinyl-based polymer segment is as follows: a vinyl-based polymer segment having a structure in which one end or both ends of the polymer chain only have the silanol group and/or the hydrolyzable silyl group is used as an intermediate; for example, in the (First method), the vinyl-based polymer segment is mixed with a silane compound having a silanol group and/or a hydrolyzable silyl group and a polymerizable double bond and optionally with a commonly used silane compound, and undergo a hydrolytic condensation reaction.

On the other hand, in the (First method) to (Third method), a specific method of combining the polysiloxane segment in the form of grafts with the vinyl-based polymer segment is as follows: a vinyl-based polymer segment having a structure in which the silanol group and/or the hydrolyzable silyl group is randomly distributed with respect to the backbone of the vinyl-based polymer segment is used as an intermediate; for example, in the (Second method), the silanol group and/or the hydrolyzable silyl group of the vinyl-based polymer segment and the silanol group and/or the hydrolyzable silyl group of the polysiloxane segment undergo a hydrolytic condensation reaction.

### (Curable Resin Composition: Polyisocyanate (B))

In the curable resin composition used in the present invention, the content of the polyisocyanate (B) with respect to the total solids weight of the curable resin composition is 5% to 50% by weight.

When the content of the polyisocyanate satisfies such a range, a shaped article having particularly high long-term outdoor weatherability (specifically, cracking resistance) can be obtained. This is probably achieved because polyisocyanate reacts with hydroxy groups in the system (these hydroxy groups are hydroxy groups in the vinyl-based polymer segment (a2) or a hydroxy group in an active-energy-ray-curable monomer having an alcoholic hydroxy group described below) to form a urethane bond, which is a soft segment and reduces concentration of stress caused by curing due to the polymerizable double bond.

When the content of the polyisocyanate (B) with respect to the total solids weight of the curable resin composition is less than 5% by weight, a shaped article formed from the composition has a problem of cracking caused upon outdoor exposure for a long period of time. On the other hand, when the content of the polyisocyanate (B) with respect to the total solids weight of the curable resin composition is high, more than 50% by weight, the shaped article has a problem of having very low scratch resistance.

The polyisocyanate (B) used is not particularly limited and may be a publicly known polyisocyanate. However, when polyisocyanates formed mainly from aromatic diisocyanates such as tolylene diisocyanate and diphenylmethane-4,4′-diisocyanate and aralkyl diisocyanates such as m-xylylene diisocyanate and α,α,α′,α′-tetramethyl-m-xylylene diisocyanate are used, the shaped articles have a problem of turning yellow upon long-term outdoor exposure. Accordingly, the amount of these polyisocyanates used is preferably minimized.

In view of outdoor usage for a long period of time, the polyisocyanate used in the present invention is preferably an aliphatic polyisocyanate formed mainly from an aliphatic diisocyanate. Examples of the aliphatic diisocyanate include tetramethylene diisocyanate, 1,5-pentamethylene diisocyanate, 1,6-hexamethylene diisocyanate (hereafter abbreviated as “HDI”), 2,2,4-(or 2,4,4-trimethyl-1,6-hexamethylene diisocyanate, lysine isocyanate, isophorone diisocyanate, hydrogenated xylene diisocyanate, hydrogenated diphenylmethane diisocyanate, 1,4-diisocyanatocyclohexane, 1,3-bis(diisocyanatomethyl)cyclohexane, and 4,4′-dicyclohexylmethane diisocyanate. In particular, HDI is preferred in view of cracking resistance and cost.

Aliphatic polyisocyanates formed from aliphatic diisocyanates include allophanate-type polyisocyanates, biuret-type polyisocyanates, adduct-type polyisocyanates, and isocyanurate-type polyisocyanates. Any of these types can be suitably used.

The polyisocyanates may be blocked polyisocyanate compounds, which have been blocked with various blocking agents. Examples of the blocking agents include alcohols such as methanol, ethanol, and lactic acid esters; phenolic-hydroxy-group-containing compounds such as phenol and salicylic acid esters; amides such as ε-caprolactam and 2-pyrrolidone; oximes such as acetone oxime and methyl ethyl ketoxime; and active-methylene compounds such as methyl acetoacetate, ethyl acetoacetate, and acetylacetone.

The content of the isocyanate group of the polyisocyanate (B) with respect to total solids weight of the polyisocyanate is preferably 3% to 30% by weight in view of cracking resistance and scratch resistance of the resultant cured coating films. When the content of the isocyanate group of (B) is less than 3%, the polyisocyanate has low reactivity and the scratch resistance becomes very low. When the content is high, more than 30%, the polyisocyanate has a low molecular weight and cracking resistance due to reduction of stress is not exhibited, which requires caution.

The reaction between the polyisocyanate and hydroxy groups in the system (these hydroxy groups are hydroxy groups in the vinyl-based polymer segment (a2) or a hydroxy group in an active-energy-ray-curable monomer having an alcoholic hydroxy group described below) does not particularly require heating or the like. For example, when an UV-curing manner is employed, the composition is applied, irradiated with UV, and then left at room temperature so that the reaction gradually proceeds. If necessary, the composition having been irradiated with UV may be heated at 80° C. for several minutes to several hours (20 minutes to 4 hours) to promote the reaction between the alcoholic hydroxy group and the isocyanate. In this case, if necessary, a publicly known urethane-forming catalyst may be used. The urethane-forming catalyst may be appropriately selected in accordance with a desired reaction temperature.

When a curable resin composition used in the present invention is cured by ultraviolet rays, which are active energy rays, a photopolymerization initiator is preferably used. The photopolymerization initiator may be a publicly known photopolymerization initiator. For example, one or more selected from the group consisting of acetophenones, benzyl ketals, and benzophenones may be used. Examples of the acetophenones include diethoxyacetophenone, 2-hydroxy-2-methyl-1-phenylpropane-1-one, 1-(4-isopropylphenyl)-2-hydroxy-2-methylpropane-1-one, and 4-(2-hydroxyethoxy)phenyl-(2-hydroxy-2-propyl) ketone. Examples of the benzyl ketals include 1-hydroxycyclohexyl-phenyl ketone and benzyl dimethyl ketal. Examples of the benzophenones include benzophenone and o-benzoyl methylbenzoate. Examples of the benzoins include benzoin, benzoin methyl ether, and benzoin isopropyl ether. The photopolymerization initiator (B) may be used alone or in combination of two or more thereof.

The content of the photopolymerization initiator (B) is preferably 1% to 15% by weight, more preferably 2% to 10% by weight, with respect to 100% by weight of the composite resin (A).

When the composition is cured by ultraviolet rays, if necessary, it preferably contains a polyfunctional (meth)acrylate. As described above, since the polyfunctional (meth)acrylate is used to react with the polyisocyanate (B), it preferably has an alcoholic hydroxy group. Examples include polyfunctional (meth)acrylates having two or more polymerizable double bonds in a molecule such as 1,2-ethanediol diacrylate, 1,2-propanediol diacrylate, 1,4-butanediol diacrylate, 1,6-hexanediol diacrylate, dipropylene glycol diacrylate, neopentyl glycol diacrylate, tripropylene glycol diacrylate, trimethylolpropane diacrylate, trimethylolpropane triacrylate, tris(2-acryloyloxy)isocyanurate, pentaerythritol triacrylate, pentaerythritol tetraacrylate, di(trimethylolpropane) tetraacrylate, di(pentaerythritol) pentaacrylate, and di(pentaerythritol) hexaacrylate. In addition, examples of the polyfunctional acrylate further include urethane acrylates, polyester acrylates, and epoxy acrylates. These may be used alone or in combination of two or more thereof.

In particular, pentaerythritol triacrylate and dipentaerythritol pentaacrylate are preferred in view of scratch resistance of cured coating films and in view of enhancement of cracking resistance as a result of reaction with polyisocyanate.

In addition to the polyfunctional (meth)acrylate, a monofunctional (meth)acrylate may also be used. Examples include hydroxy-group-containing (meth)acrylates such as hydroxyethyl (meth)acrylate, hydroxypropyl (meth)acrylate, hydroxybutyl (meth)acrylate, caprolactone-modified hydroxy (meth)acrylate (for example, “PLACCEL”, trade name, manufactured by DAICEL CHEMICAL INDUSTRIES, LTD.), mono(meth)acrylate of polyesterdiol obtained from phthalic acid and propylene glycol, mono(meth)acrylate of polyesterdiol obtained from succinic acid and propylene glycol, polyethylene glycol mono(meth)acrylate, polypropylene glycol mono(meth)acrylate, pentaerythritol tri(meth)acrylate, 2-hydroxy-3-(meth)acryloyloxypropyl (meth)acrylate, and (meth)acrylic acid adducts of various epoxyesters; carboxyl-group-containing vinyl monomers such as (meth)acrylic acid, crotonic acid, itaconic acid, maleic acid, and fumaric acid; sulfonic-group-containing vinyl monomers such as vinylsulfonic acid, styrenesulfonic acid, and sulfoethyl (meth)acrylate; acid-phosphate-based vinyl monomers such as 2-(meth)acryloyloxyethyl acid phosphate, 2-(meth)acryloyloxypropyl acid phosphate, 2-(meth)acryloyloxy-3-chloro-propyl acid phosphate, and 2-methacryloyloxyethylphenyl phosphate; and methylol-group-containing vinyl monomers such as N-methylol (meth)acrylamide. These may be used alone or in combination of two or more thereof. In particular, in view of reactivity with the isocyanate group of the polyfunctional isocyanate (b), hydroxy-group-containing (meth)acrylates are preferred as the monomer (c).

When the polyfunctional acrylate (C) is used, the content thereof with respect to the total solids weight of the curable resin composition used in the present invention is preferably 1% to 85% by weight, more preferably 5% to 80% by weight. When the polyfunctional acrylate is used so as to satisfy such a range, properties of the resultant shaped article such as hardness can be improved.

As to light used for ultraviolet curing, those usable include, for example, a low-pressure mercury-vapor lamp, a high-pressure mercury-vapor lamp, a metal halide lamp, a xenon lamp, argon laser, helium-cadmium laser, and an ultraviolet-emitting diode. By using these, the surface of the curable resin composition applied can be irradiated with ultraviolet rays having a wavelength of about 180 to 400 nm to cure the composition. The dose of ultraviolet rays is appropriately selected in accordance with the type and amount of a photopolymerization initiator used.

On the other hand, when the curable resin composition used in the present invention is cured by heat, the catalysts are preferably selected in consideration of the reaction temperature, reaction time, and the like of the polymerizable double bond reaction and the urethane-forming reaction between an alcoholic hydroxy group and isocyanate in the composition.

In addition, a thermosetting resin may also be used. Examples of the thermosetting resin include vinyl-based resins, unsaturated polyester resins, polyurethane resins, epoxy resins, epoxyester resins, acrylic resins, phenol resins, petroleum resins, ketone resins, silicone resins, and modified resins of the foregoing.

To adjust the viscosity during coating, the composition may contain an organic solvent. Examples of the organic solvent include aliphatic or alicyclic hydrocarbons such as n-hexane, n-heptane, n-octane, cyclohexane, and cyclopentane; aromatic hydrocarbons such as toluene, xylene, and ethylbenzene; alcohols such as methanol, ethanol, n-butanol, ethylene glycol monomethyl ether, and propylene glycol monomethyl ether; esters such as ethyl acetate, butyl acetate, n-butyl acetate, n-amyl acetate, ethylene glycol monomethyl ether acetate, and propylene glycol monomethyl ether acetate; ketones such as acetone, methyl ethyl ketone, methyl isobutyl ketone, methyl n-amyl ketone, and cyclohexanone; polyalkylene glycol dialkyl ethers such as diethylene glycol dimethyl ether and diethylene glycol dibutyl ether; ethers such as 1,2-dimethoxyethane, tetrahydrofuran, and dioxane; N-methylpyrrolidone, dimethylformamide, dimethylacetamide, and ethylene carbonate. These solvents may be used alone or in combination of two or more thereof.

In addition, if necessary, the curable resin composition used in the present invention may further contain various additives such as organic solvents, inorganic pigments, organic pigments, body pigments, clay minerals, waxes, surfactants, stabilizers, flow modifiers, dyes, leveling agents, rheology controlling agents, UV absorbing agents, antioxidants, and plasticizers.

Since a curable resin composition used in the present invention contains the composite resin (A) containing both the polysiloxane segment (a1) and the vinyl-based polymer segment (a2), it is relatively compatible with silicone resins that can enhance, for example, the surface smoothness of coating films, acrylic-based resins, and active-energy-ray-curable monomers. Accordingly, a composition having high compatibility can be obtained.

### (Method for Producing Shaped Article Having Irregularities)

Specifically, a shaped article having surface irregularities according to the present invention is obtained in the following manner. The curable resin composition is processed with a mold or the like so as to have the shape of the shaped article or, for example, applied to a base or the like so as to form a film and processed by a publicly known method so as to have a fine structure including projections and a recess formed between the projections; and the curable resin composition is then cured.

Examples of a method for providing the shape of the shaped article with a mold or the like include injection molding, matched mold forming, and cast molding. Into a mold in which a fine structure including projections and a recess formed between the projections has been formed in advance, the curable resin composition melted by heating and having liquid form is poured. Subsequently, the curable resin composition is cured by heat, an active energy ray, or the like. The composition is then released from the mold to provide a shaped article having surface irregularities according to the present invention. For example, in the case of injection molding, into an injection mold in which a fine structure including projections and a recess formed between the projections has been formed in advance, the curable resin composition melted by heating is injected; subsequently, the composition is cooled with the temperature of the mold and then released from the mold to provide a shaped article having a surface in which the fine structure of the mold is formed.

Examples of a method for forming the shaped article by forming a film-shaped curable-resin-composition layer through application or the like on a surface of a base or the like and by curing the curable-resin-composition layer include a method of using a particle mask described in Japanese Unexamined Patent Application Publication Nos. 2001-155623, 2005-99707, 2005-279807, and the like; a method of using hologram lithography described in Thin Solid Films 351 (1999) 73-78; a method of using electron beam lithography or laser beam lithography described in Japanese Unexamined Patent Application Publication No. 2003-4916; a method of performing embossing such as nanoimprinting; a method of performing plasma processing; and printing methods such as offset printing, flexographic printing, gravure printing, screen printing, inkjet printing, and sublimation transfer. In particular, a method of performing embossing is preferred because a high-precision pattern can be imparted to flat and large-area molded articles and high productivity can be achieved. Representative techniques include UV embossing and nanoimprinting.

A method for providing the shape of the shaped article by UV embossing can be performed in the following manner. On the curable-resin-composition layer disposed on a surface of a base or the like, an embossing roll having a fine pattern in its surface is moved while the curable resin composition is applied to the resin-film base; the UV curable resin is cured by UV irradiation while the embossing roll is engaged in the application surface and the roll is rotated; after the curing, the UV cured resin layer together with the resin-film base is released from the embossing roll to thereby form a film having a surface to which the shape of the fine pattern has been transferred.

A method for providing the shape of the shaped article by nanoimprinting can be performed in the following manner. Into the curable-resin-composition layer disposed on a surface of a base or the like, a nanoimprinting mold is pressed under heating so that the softened curable-resin-composition layer enters the fine structure of the mold; subsequently, the curable-resin-composition layer is cooled and the nanoimprinting mold is then released, or the curable-resin-composition layer is cured by UV irradiation and the nanoimprinting mold is then released, to thereby provide a shaped article in which the fine structure of the nanoimprinting mold has been formed in the surface of the curable-resin layer.

Specifically, a nanoimprinting mold is brought into contact with and pressed into the curable-resin-composition layer disposed on a surface of a base or the like, so that the curable-resin-composition layer is sandwiched. As a method for efficiently producing a large-area shaped article, the nanoimprinting mold may be preferably brought into contact by a method compatible with a roll process, such as an up-down mode of a flat template, a bonding mode of a belt-shaped template, a roll transfer mode of a roll-shaped template, or a roll transfer mode of a roll-belt-shaped template. Examples of the material of the nanoimprinting mold include light transmitting materials such as quartz glass, UV transmitting glass, sapphire, diamond, silicone materials such as polydimethylsiloxane, fluorocarbon resins, and other light transmitting resin materials. When the curable resin composition is cured by heating or, even in the case of curing by light, when the base is composed of a light transmitting material, the nanoimprinting mold may be composed of a light non-transmitting material. Examples of the light non-transmitting material include metals, silicone, SiC, and mica.

As described above, the nanoimprinting mold may have a desired shape selected from a flat shape, a belt shape, a roll shape, a roll-belt shape, and the like. For the purpose of, for example, suppressing pollution of the template due to suspended dust or the like, the transfer surface is preferably subjected to a publicly known release treatment.

In the method of forming a film of the curable resin composition on a base or the like by UV embossing or nanoimprinting, when the base is a three-dimensionally-shaped article or member, the film is preferably formed by a publicly known and commonly used coating method such as a brush coating, roller coating, spray coating, dip coating, flow-coater coating, roll-coater coating, or electrodeposition coating.

On the other hand, when a film is formed by employing, as a base, a flexible sheet, the resin-composition layer may be formed on a sheet-shaped plastic base by a flow coater, a roll coater, blasting, airless spraying, air spraying, brush coating, roller coating, troweling, dipping, Czochralski method, a nozzle process, roll process, a flowing process, potting process, patching, or the like. Although the film thickness highly depends on a desired irregularity depth, it is preferably in the range of 0.03 to 300 μm.

### (Base)

The base may be various bases such as metal bases, inorganic bases, plastic bases, papers, and woody bases.

The plastic bases may be formed of polyolefins such as Polyethylene, polypropylene, and ethylene-propylene copolymers; polyesters such as polyethylene isophthalate, polyethylene terephthalate, polyethylene naphthalate, and polyethylene terephthalate; polyamides such as nylon 1, nylon 11, nylon 6, nylon 66, and nylon MX-D; styrene-based polymers such as polystyrene, styrene-butadiene block copolymers, styrene-acrylonitrile copolymers, and styrene-butadiene-acrylonitrile copolymers (ABS resins); acrylic-based polymers such as polymethyl methacrylate and methyl methacrylate-ethyl acrylate copolymers; and polycarbonate. The plastic bases may be constituted by a monolayer or may have a multilayer structure of two or more layers. The plastic bases may be undrawn, uniaxially drawn, or biaxially drawn.

If necessary, as long as advantages of the present invention are not degraded, the plastic bases may contain publicly known additives such as antistatic agents, antifogging agents, anti-blocking agents, UV absorbing agents, antioxidants, light stabilizers, nucleating agents, and slip additives.

The surfaces of the plastic bases may be subjected to publicly known surface treatments for the purpose of further enhancing adhesion to the curable resin composition used in the present invention. Examples of the surface treatments include a corona discharge treatment, a plasma treatment, a flame plasma treatment, an electron-beam irradiation treatment, and an ultraviolet irradiation treatment. These treatments may be used alone or in combination of two or more thereof.

The shape of the base is not particularly limited. The base may have the shape of a sheet, a plate, a sphere, or a film, or may be a large structure or a complex assembly or shaped article.

### (Curing Step)

Curing in UV embossing or nanoimprinting may be achieved by using an active energy ray or heat. In view of causing curing to proceed at a low temperature (enhancing reactivity), in particular, a method in which the photopolymerization initiator is used as a polymerization initiator and the curable-resin-composition layer is cured by photoirradiation is preferred. As to the photoirradiation, in the case of curing at a low temperature, when an embossing roll or a mold is composed of a light transmitting material, light may be applied through the embossing roll or the mold; when a base is composed of a light transmitting material, light may be applied through the base. The light used for photoirradiation is a light that can cause the reaction of the photopolymerization initiator. In particular, lights having a wavelength of 450 nm or less (active energy rays such as ultraviolet rays, X-rays, and γ-rays) are preferred because the lights can easily cause the reaction of the photopolymerization initiator and curing can be achieved at a lower temperature. In view of operability, lights having a wavelength of 200 to 450 nm are particularly preferred. Specifically, lights used in the above-described ultraviolet curing can be used.

The reactant during photoirradiation may be heated to promote the curing. The temperature in the heating is preferably 300° C. or less, more preferably 0° C. to 200° C., still more preferably 0° C. to 150° C., particularly preferably 25° C. to 80° C. In such a temperature range, the high accuracy of the fine pattern structure formed in the curable-resin-composition layer is maintained. Alternatively, the curable-resin-composition layer may be cured by heating alone without photoirradiation.

In any of the above-described manners, as a method for efficiently producing a large-area shaped article, curing may be preferably performed by a transfer method within a reaction apparatus so as to be compatible with a roll process.

### (Release Step)

After the curing step, the shaped article is released from the embossing roll or the mold to provide the shaped article in which an irregular pattern is formed in the surface of the cured article of the curable-resin-composition layer, the irregular pattern being transferred from and in inverse relation to the irregular pattern of the embossing roll or the mold. In view of suppressing deformation of the shaped article such as warpage or enhancing the accuracy of the irregular pattern, as to the temperature in the release step, the release step is preferably performed after the temperature of the shaped article decreases to about room temperature (25° C.); or, even when the shaped article is released at a temperature that is about the reaction temperature of the curing step, the shaped article is preferably cooled to about room temperature (25° C.) under a certain tension.

The embossing roll or the nanoimprinting mold used in the UV embossing may be a shaped article according to the present invention. In this case, when the transfer body is produced from a photo/thermocurable composition serving as a transfer material, the surface of a shaped article according to the present invention is preferably subjected to a publicly known release treatment.

When the thus-produced shaped article having surface irregularities is used in, for example, optical part applications such as optical lenses, light guide plates, diffusion plates, nonreflective films, polarizing films for display apparatuses, or transmissive films for solar-cell devices, or building applications such as photocatalytic films, antiglare films, or antifouling films, the irregularities preferably have a depth in the range of 0.01 to 50 μm and, in at least one direction, a pitch in the range of 0.01 to 50 μm; preferred examples of the structure of the irregularities include a lens structure, a pillar structure, a line and space structure, a grid structure, a pyramid structure, a honeycomb structure, a dot structure, a desired structure intended for nanochannels or the like, a wavelike structure to which an interference exposure technique is applied, and composite structures in which the foregoing structures are combined. The structure may be one in which such structures are horizontally combined together, a monolayer structure, or a vertically stacked multilayer structure.

### (Protective Sheet for Solar Cell)

A shaped article obtained by the present invention may be used as a member constituting a surface protective member for a light-receiving surface of a solar-cell module. Specifically, a curable-resin-composition layer used in the present invention is formed on a single surface of a plastic substrate; irregularities are then formed by various methods and the layer is cured. Thus, the shaped article can be suitably used as a surface protective member for a light-receiving surface of a solar-cell module, specifically, as a solar-cell protective sheet.

In order to develop a solar-cell module having a high power generation efficiency, a solar-cell protective sheet providing a high light-receiving effect has been demanded. As a method for enhancing the light-receiving effect of a solar-cell protective sheet, a method for providing a light-receiving effect has been generally studied in which a geometric three-dimensional structure is formed from resin on a glass surface so that the incident angle of light at the time of oblique incidence is converted to a smaller angle or reflected light is made incident again.

In the present invention, the composite resin (A) layer is formed on a single surface of a plastic substrate, irregularities are then formed by various methods, and the layer is cured. Thus, a surface protective member for a light-receiving surface of a solar-cell module, the member having excellent long-term weatherability and a high light-receiving efficiency, can be formed. A solar-cell module including the surface protective member for a light-receiving surface of a solar-cell module has a high power generation capability and long-term weatherability even outdoors.

### (Plastic Substrates)

Examples of a plastic substrate used in the present invention include films and sheets of polyolefin-based resins such as polyethylene (PE) (high-density polyethylene, low-density polyethylene, and linear low-density polyethylene), polypropylene (PP), and polybutene, (meth)acrylic-based resins, polyvinyl chloride-based resins, polystyrene-based resins, polyvinylidene chloride-based resins, saponified products of ethylene-vinyl acetate copolymers, polyvinyl alcohol, polycarbonate-based resins, fluorocarbon resins, polyvinyl acetate-based resins, acetal-based resins, polyester-based resins (polyethylene terephthalate (PET), polybutylene terephthalate, and polyethylene naphthalate), polyamide-based resins, polyphenylene sulfide (PPS) resins, and other various resins. The films and sheets of such resins may be uniaxially or biaxially drawn. Such resin films may be stacked to form a multilayer structure. A metal oxide and an inorganic compound may be deposited on such resin films. As long as advantages of the present invention are not degraded, such resin films may contain publicly known additives such as UV absorbing agents, water absorbing agents (drying agents), oxygen absorbing agents, and antioxidants. In particular, in consideration of properties of a protective sheet for a solar cell, such as transparency, preferably used are polyolefin-based resins such as polyethylene (PE) (high-density polyethylene, low-density polyethylene, and linear low-density polyethylene), polypropylene (PP), and polybutene, (meth)acrylic-based resins, polyester-based resins (polyethylene terephthalate (PET), polybutylene terephthalate, and polyethylene naphthalate), polyphenylene sulfide (PPS) resins, and the like.

On a single surface of the plastic substrate, a curable-resin-composition layer containing the composite resin (A) is formed. The process for forming the curable-resin-composition layer may be a publicly known process. Examples of the process include a calender process, a flow-coater process, a roll-coater process, blasting, airless spraying, air spraying, brush coating, roller coating, troweling, dipping, a withdrawal process, a nozzle process, a roll process, a flowing process, piling up, and patching.

The film thickness of the curable-resin-composition layer is preferably in the range of 0.05 μm to 150 μm. When the film thickness is less than 0.05 μm, the ultraviolet-shielding capability may be insufficient. When the film thickness is more than 150 μm, cracking may be caused in the coating film during subsequent steps.

### (Method for Producing Solar-Cell Protective Sheet Having Surface Irregularities)

A mold having a fine surface pattern is pressed into the curable-resin-composition layer; in this state, the curable-resin-composition layer is cured by active-energy-ray curing, thermal curing, or active-energy-ray and thermal curing; and the mold is released. As a result, a solar-cell protective sheet having a fine surface pattern can be obtained.

Examples of a process of pressing the mold are as follows: a roll-shaped mold is used and while a plastic substrate is in contact with the roll, the roll is rotated and pressed into the plastic substrate; a flat-plate-shaped mold is used, and the mold surface and a plastic substrate surface disposed in parallel are pressed into each other.

The curable resin composition is preferably cured by active-energy-ray curing in view of production efficiency. The active energy rays are preferably lights having a wavelength of 450 nm or less (ultraviolet rays, X-rays, γ-rays, and the like), which allow curing of the curable resin composition at a lower temperature; particularly preferably ultraviolet rays having a wavelength of 200 to 450 nm in view of operability. When a mold and a plastic substrate that transmit ultraviolet rays are used, ultraviolet rays may be applied through the mold or the plastic substrate. When a mold that does not transmit ultraviolet rays such as a metal mold is used, ultraviolet rays may be applied through the transparent plastic substrate.

The curable-resin-composition layer in which irregularities have been formed is cured by the above-described active-energy-ray curing, thermal curing, or active-energy-ray and thermal curing. As a result, a solar-cell protective sheet having a cured protective layer can be obtained.

The haze of the protective layer may be selected in general consideration of the strength or durability of the coating film or the conversion efficiency of the solar cell. In view of the conversion efficiency of the solar cell, the haze is preferably 20 or less, more preferably 10 or less, still more preferably 5 or less.

The solar-cell protective sheet can be suitably used as a protective sheet for a light-receiving surface of a solar-cell module.

For example, when the sheet is used as a protective sheet for a light-receiving surface, the metal oxide is preferably zinc oxide having high transparency. In this case, the amount of zinc oxide added is preferably 1% to 25%, most preferably 1.5% to 20%.

### (Solar-Cell Module)

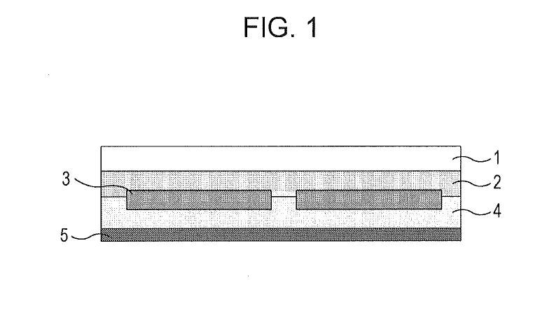

FIG. 1 illustrates a specific embodiment of the solar-cell module in the case of using a solar-cell protective sheet according to the present invention as a protective sheet for a light-receiving surface. Note that the present invention clearly encompasses various embodiments and the like that are not described here.

In the solar-cell module illustrated in FIG. 1, a solar-cell protective sheet 1 for a light-receiving surface, a first sealing material 2, a solar-cell group 3, a second sealing material 4, and a solar-cell protective sheet 5 are sequentially stacked. The solar-cell protective sheet 1 for a light-receiving surface is formed such that the plastic substrate of the protective sheet 1 (a surface opposite to the cured surface of the curable-resin-composition layer containing the composite resin (A) according to the present invention) is in contact with the first sealing material 2, that is, the protective layer formed by curing the curable resin composition serves as an uppermost layer.

The first sealing material 2 and the second sealing material 4 are disposed between the solar-cell protective sheet 1 according to the present invention and the cell protective sheet 5 and seal the solar-cell group 3. The first sealing material 2 and the second sealing material 4 may be formed of light transmitting resins such as EVA, EEA, PVB, silicone, urethane, acrylic, and epoxy. The first sealing material 2 and the second sealing material 4 contain a crosslinking agent such as peroxide. Accordingly, when the first sealing material 2 and the second sealing material 4 are heated to a temperature equal to or more than the predetermined crosslinking temperature, they are softened and then crosslinking is initiated.

The solar-cell group 3 includes a plurality of solar cells and wiring members. The plurality of solar cells are electrically interconnected through the wiring members.

After that, the first sealing material 2 and the second sealing material 4 that are laminated with a laminator are cured by heating. Thus, a solar-cell module can be obtained.

### EXAMPLES

Hereinafter, the present invention will be specifically described with reference to Examples and Comparative examples. In EXAMPLES, “part” and “%” are based on weight unless otherwise specified.

### Synthesis Example 1

### Preparation Example of Polysiloxane

A reaction vessel equipped with a stirrer, a thermometer, a dropping funnel, a condenser, and a nitrogen-gas inlet was charged with 415 parts of methyltrimethoxysilane (MTMS) and 756 parts of 3-methacryloyloxypropyltrimethoxysilane (MPTS). While being stirred under bubbling of a nitrogen gas, the solution was heated to 60° C. Subsequently, a mixture composed of 0.1 parts of “A-3” [iso-propyl acid phosphate manufactured by Sakai Chemical Industry Co., Ltd.] and 121 parts of deionized water was dropped over 5 minutes. After the dropping was completed, the solution in the reaction vessel was heated to 80° C. and stirred for 4 hours to cause a hydrolytic condensation reaction. Thus, a reaction product was obtained.

Methanol and water contained in the obtained reaction product were removed under a reduced pressure of 1 to 30 kilopascals (kPa) at 40° C. to 60° C. Thus, 1000 parts of a polysiloxane (a1-1) having a number-average molecular weight of 1000 and an effective content of 75.0% was obtained.

Note that the “effective content” was a value calculated by dividing a theoretical yield (parts by weight) in the case where all the methoxy groups in the silane monomers used undergo the hydrolytic condensation reaction by the actual yield (parts by weight) after the hydrolytic condensation reaction, that is, calculated with a formula [theoretical yield (parts by weight) in the case where all the methoxy groups in the silane monomers undergo the hydrolytic condensation reaction/actual yield (parts by weight) after the hydrolytic condensation reaction].

### Synthesis Example 2

### Same as Above

A reaction vessel as in Synthesis example 1 was charged with 442 parts of MTMS and 760 parts of 3-acryloyloxypropyltrimethoxysilane (APTS). While being stirred under bubbling of a nitrogen gas, the solution was heated to 60° C. Subsequently, a mixture composed of 0.1 parts of “A-3” and 129 parts of deionized water was dropped. over 5 minutes. After the dropping was completed, the solution in the reaction vessel was heated to 80° C. and stirred for 4 hours to cause a hydrolytic condensation reaction. Thus, a reaction product was obtained. Methanol and water contained in the obtained reaction product were removed under a reduced pressure of 1 to 30 kilopascals (kPa) at 40° C. to 60° C. Thus, 1000 parts of a polysiloxane (a1-2) having a number-average molecular weight of 1000 and an effective content of 75.0% was obtained.

### Synthesis Example 3

### Preparation Example of Vinyl-Based Polymer (a2-1)

A reaction vessel as in Synthesis example 1 was charged with 20.1 parts of phenyltrimethoxysilane (PTMS), 24.4 parts of dimethyldimethoxysilane (DMDMS), and 35.9 parts of isopropyl alcohol. While being stirred under bubbling of a nitrogen gas, the solution was heated to 80° C. Subsequently, into the solution in the reaction vessel being stirred under bubbling of a nitrogen gas at the same temperature, a mixture composed of 22.6 parts of n-butyl methacrylate, 27.7 parts of n-butyl acrylate, 1.3 parts of acrylic acid, 3.8 parts of MPTS, 37.5 parts of β-hydroxyethyl methacrylate, and 15 parts of tert-butylperoxy-2-ethyl hexanoate (TBPEH) was dropped over 4 hours. The solution was further stirred at the same temperature for 2 hours. Into the reaction vessel, a mixture composed of 0.05 parts of “A-3” and 12.8 parts of deionized water was then dropped over 5 minutes. The solution was stirred at the same temperature for 4 hours to cause a hydrolytic condensation reaction between PTMS, DMDMS, and MPTS. The reaction product was analyzed by ¹H-NMR and substantially 100% of the trimethoxysilyl group of the silane monomer in the reaction vessel was hydrolyzed. The solution was then stirred at the same temperature for 10 hours. Thus, a vinyl-based polymer (a2-1) that was a reaction product in which the residual content of TBPEH was 0.1% or less was obtained.

### Synthesis Example 4

### Preparation Example of Composite Resin (A)

A reaction vessel as in Synthesis example 1 was charged with 20.1 parts of phenyltrimethoxysilane (PTMS), 24.4 parts of dimethyldimethoxysilane (DMDMS), and 107.7 parts of n-butyl acetate. While being stirred under bubbling of a nitrogen gas, the solution was heated to 80° C. Subsequently, into the solution in the reaction vessel being stirred under bubbling of a nitrogen gas at the same temperature, a mixture composed of 15 parts of methyl methacrylate (MMA), 45 parts of n-butyl methacrylate (BMA), 39 parts of 2-ethylhexyl methacrylate (EHMA), 1.5 parts of acrylic acid (AA), 4.5 parts of MPTS, 45 parts of 2-hydroxyethyl methacrylate (HEMA), 15 parts of n-butyl acetate, and 15 parts of tert-butylperoxy-2-ethyl hexanoate (TBPEH) was dropped over 4 hours. The solution was further stirred at the same temperature for 2 hours. Into the reaction vessel, a mixture composed of 0.05 parts of “A-3” and 12.8 parts of deionized water was then dropped over 5 minutes. The solution was then stirred at the same temperature for 4 hours to cause a hydrolytic condensation reaction between PTMS, DMDMS, and MPTS. The reaction product was analyzed by ¹H-NMR and substantially 100% of the trimethoxysilyl group of the silane monomer in the reaction vessel was hydrolyzed. The solution was then stirred at the same temperature for 10 hours. Thus, a reaction product in which the residual content of TBPEH was 0.1% or less was obtained. Note that the residual content of TBPEH was determined by iodometric titration.

To the reaction product, 162.5 parts of the polysiloxane (a1-1) obtained in Synthesis example 1 was then added. The solution was stirred for 5 minutes, then mixed with 27.5 parts of deionized water, and stirred at 80° C. for 4 hours to cause a hydrolytic condensation reaction between the reaction product and the polysiloxane. The resultant reaction product was distilled under a reduced pressure of 10 to 300 kPa at 40° C. to 60° C. for 2 hours to remove generated methanol and water. Subsequently, 150 parts of methyl ethyl ketone (MEK) and 27.3 parts of n-butyl acetate were added. Thus, 600 parts of a composite resin (A-1) including a polysiloxane segment and a vinyl polymer segment and having a nonvolatile content of 50.0% was obtained.

### Synthesis Example 5

### Same as Above

A reaction vessel as in Synthesis example 1 was charged with 20.1 parts of PTMS, 24.4 parts of DMDMS, and 107.7 parts of n-butyl acetate. While being stirred under bubbling of a nitrogen gas, the solution was heated to 80° C. Subsequently, into the solution in the reaction vessel being stirred under bubbling of a nitrogen gas at the same temperature, a mixture composed of 15 parts of MMA, 45 parts of BMA, 39 parts of EHMA, 1.5 parts of AA, 4.5 parts of MPTS, 45 parts of HEMA, 15 parts of n-butyl acetate, and 15 parts of TBPEH was dropped over 4 hours. The solution was further stirred at the same temperature for 2 hours. Into the reaction vessel, a mixture composed of 0.05 parts of “A-3” and 12.8 parts of deionized water was then dropped over 5 minutes. The solution was stirred at the same temperature for 4 hours to cause a hydrolytic condensation reaction between PTMS, DMDMS, and MPTS. The reaction product was analyzed by ¹H-NMR and substantially 100% of the trimethoxysilyl group of the silane monomer in the reaction vessel was hydrolyzed. The solution was then stirred at the same temperature for 10 hours. Thus, a reaction product in which the residual content of TBPEH was 0.1% or less was obtained. Note that the residual content of TBPEH was determined by iodometric titration.

To the reaction product, 562.5 parts of the polysiloxane (a1-1) obtained in Synthesis example 1 was then added. The solution was stirred for 5 minutes, then mixed with 80.0 parts of deionized water, and stirred at 80° C. for 4 hours to cause a hydrolytic condensation reaction between the reaction product and the polysiloxane. The resultant reaction product was distilled under a reduced pressure of 10 to 300 kPa at 40° C. to 60° C. for 2 hours to remove generated methanol and water. Subsequently, 128.6 parts of MEK and 5.8 parts of n-butyl acetate were added. Thus, 857 parts of a composite resin (A-2) including a polysiloxane segment and a vinyl polymer segment and having a nonvolatile content of 70.0% was obtained.

### Synthesis Example 6

### Same as Above

A reaction vessel as in Synthesis example 1 was charged with 20.1 parts of PTMS, 24.4 parts of DMDMS, and 107.7 parts of n-butyl acetate. While being stirred under bubbling of a nitrogen gas, the solution was heated to 80° C. Subsequently, into the solution in the reaction vessel being stirred under bubbling of a nitrogen gas at the same temperature, a mixture composed of 15 parts of MMA, 45 parts of BMA, 39 parts of EHMA, 1.5 parts of AA, 4.5 parts of MPTS, 45 parts of HEMA, 15 parts of n-butyl acetate, and 15 parts of TBPEH was dropped over 4 hours. The solution was further stirred at the same temperature for 2 hours. Into the reaction vessel, a mixture composed of 0.05 parts of “A-3” and 12.8 parts of deionized water was then dropped over 5 minutes. The solution was stirred at the same temperature for 4 hours to cause a hydrolytic condensation reaction between PTMS, DMDMS, and MPTS. The reaction product was analyzed by ¹H-NMR and substantially 100% of the trimethoxysilyl group of the silane monomer in the reaction vessel was hydrolyzed. The solution was then stirred at the same temperature for 10 hours. Thus, a reaction product in which the residual content of TBPEH was 0.1% or less was obtained. Note that the residual content of TBPEH was determined by iodometric titration.

To the reaction product, 162.5 parts of the polysiloxane (a1-2) obtained in Synthesis example 2 was then added. The solution was stirred for 5 minutes, then mixed with 27.5 parts of deionized water, and stirred at 80° C. for 4 hours to cause a hydrolytic condensation reaction between the reaction product and the polysiloxane. The resultant reaction product was distilled under a reduced pressure of 10 to 300 kPa at 40° C. to 60° C. for 2 hours to remove generated methanol and water. Subsequently, 150 parts of MEK and 27.3 parts of n-butyl acetate were added. Thus, 600 parts of a composite resin (A-3) including a polysiloxane segment and a vinyl polymer segment and having a nonvolatile content of 50.0% was obtained.

### Synthesis Example 7

### Same as Above

A reaction vessel as in Synthesis example 1 was charged with 17.6 parts of PTMS, 21.3 parts of DMDMS, and 129.0 parts of n-butyl acetate. While being stirred under bubbling of a nitrogen gas, the solution was heated to 80° C. Subsequently, into the solution in the reaction vessel being stirred under bubbling of a nitrogen gas at the same temperature, a mixture composed of 21 parts of MMA, 63 parts of BMA, 54.6 parts of EHMA, 2.1 parts of AA, 6.3 parts of MPTS, 63 parts of HEMA, 21 parts of n-butyl acetate, and 21 parts of TBPEH was dropped over 4 hours. The solution was further stirred at the same temperature for 2 hours. Into the reaction vessel, a mixture composed of 0.04 parts of “A-3” and 11.2 parts of deionized water was then dropped over 5 minutes. The solution was stirred at the same temperature for 4 hours to cause a hydrolytic condensation reaction between PTMS, DMDMS, and MPTS. The reaction product was analyzed by ¹H-NMR and substantially 100% of the trimethoxysilyl group of the silane monomer in the reaction vessel was hydrolyzed. The solution was then stirred at the same temperature for 10 hours. Thus, a reaction product in which the residual content of TBPEH was 0.1% or less was obtained. Note that the residual content of TBPEH was determined by iodometric titration.

To the reaction product, 87.3 parts of the polysiloxane (a1-1) obtained in Synthesis example 1 was then added. The solution was stirred for 5 minutes, then mixed with 12.6 parts of deionized water, and stirred at 80° C. for 4 hours to cause a hydrolytic condensation reaction between the reaction product and the polysiloxane. The resultant reaction product was distilled under a reduced pressure of 10 to 300 kPa at 40° C. to 60° C. for 2 hours to remove generated methanol and water. Subsequently, 150 parts of MEK was added. Thus, 600 parts of a composite resin (A-4) including a polysiloxane segment and a vinyl polymer segment and having a nonvolatile content of 50.0% was obtained.

To 346 parts of the vinyl-based polymer (a2-1) obtained in Synthesis example 2, 148 parts of n-butyl methacrylate was added and 162.5 parts of the polysiloxane (a1-1) obtained in Synthesis example 1 was added. The solution was stirred for 5 minutes, then mixed with 27.5 parts of deionized water, and stirred at 80° C. for 4 hours to cause a hydrolytic condensation reaction between the reaction product and the polysiloxane. The resultant reaction product was distilled under a reduced pressure of 10 to 300 kPa at 40° C. to 60° C. for 2 hours to remove generated methanol and water. Thus, 400 parts of a composite resin (A-5) including the polysiloxane segment (a1-1) and the vinyl-based polymer segment (a2-1) and having a nonvolatile content of 72% was obtained.

### Comparative Synthesis Example 1

### Preparation of Comparative Resin (R-1)

A vessel as in Synthesis example 1 was charged with 107.7 parts of n-butyl acetate. While being stirred under bubbling of a nitrogen gas, n-butyl acetate was heated to 80° C. Subsequently, into the solution in the reaction vessel being stirred under bubbling of a nitrogen gas at the same temperature, a mixture composed of 15 parts of methyl methacrylate (MMA), 45 parts of n-butyl methacrylate (BMA), 39 parts of 2-ethylhexyl methacrylate (EHMA), 1.5 parts of acrylic acid (AA), 45 parts of 2-hydroxyethyl methacrylate (HEMA), 15 parts of n-butyl acetate, and 15 parts of tert-butylperoxy-2-ethyl hexanoate (TBPEH) was dropped over 4 hours. The solution was then further stirred at the same temperature for 10 hours. Thus, a comparative resin intermediate that was a reaction product in which the residual content of TBPEH was 0.1% or less was obtained.

Subsequently, 123 parts of 3-methacryloyloxypropyltrimethoxysilane (MPTS) was added and then a mixture composed of 0.1 parts of “A-3” [iso-propyl acid phosphate manufactured by Sakai Chemical Industry Co., Ltd.] and 121 parts of deionized water was dropped over 5 minutes. After the dropping was completed, the solution in the reaction vessel was then heated to 80° C. and stirred for 4 hours to cause a hydrolytic condensation reaction. Thus, a reaction product was provided. The obtained reaction product was distilled under a reduced pressure of 10 to 300 kPa at 40° C. to 60° C. for 2 hours to remove generated methanol and water. Subsequently, 150 parts of methyl ethyl ketone (MEK) and 27.3 parts of n-butyl acetate were then added. Thus, a comparative resin (R-1) having a nonvolatile content of 50.0% was obtained.

### Comparative Synthesis Example 2

### Preparation of Comparative Composite Resin (R-2)

A reaction vessel as in Synthesis example 1 was charged with 191 parts of PTMS. While being stirred under bubbling of a nitrogen gas, PTMS was heated to 120° C. Subsequently, into the solution in the reaction vessel being stirred under bubbling of a nitrogen gas at the same temperature, a mixture composed of 169 parts of MMA, 11 parts of MPTS, and 18 parts of TBPEH was dropped over 4 hours. After that, the solution was stirred at the same temperature for 16 hours to prepare an acrylic polymer having a trimethoxysilyl group.

The temperature of the reaction vessel was then adjusted to be 80° C. To the solution in the reaction vessel being stirred, a mixture composed of 131 parts of MTMS, 226 parts of APTS, and 116 parts of DMDMS was added. Subsequently, a mixture composed of 6.3 parts of “A-3” and 97 parts of deionized water was dropped over 5 minutes. The solution was stirred at the same temperature for 2 hours to cause a hydrolytic condensation reaction. Thus, a reaction product was provided. The reaction product was analyzed by ¹H-NMR and substantially 100% of the trimethoxysilyl group of the acrylic polymer was hydrolyzed. The reaction product obtained was distilled under a reduced pressure of 10 to 300 kPa at 40° C. to 60° C. for 2 hours to remove generated methanol and water. Subsequently, 400 parts of n-butyl acetate was added. Thus, 600 parts of a comparative composite resin (R-2) including a polysiloxane segment and an acrylic polymer segment and having a nonvolatile content of 60.0% was obtained. Note that this synthesis example was performed in accordance with Synthesis example 1 described in EXAMPLES of PTL 2.

### Example 1

### Method for Producing Shaped Article Having Surface Irregularities

A curable resin composition (composition-1) was obtained by mixing 40.0 parts of the composite resin (A-1) obtained in Synthesis example 1, 7.0 parts of pentaerythritol triacrylate (PETA), 1.08 parts of IRGACURE 184 [photopolymerization initiator, manufactured by Ciba Japan K. K.], 0.67 parts of TINUVIN 400 [hydroxyphenyl triazine-based UV absorbing agent, manufactured by Ciba Japan K. K.], 0.34 parts of TINUVIN 123 [hindered amine-based light stabilizer (HALS), manufactured by Ciba Japan K. K.], and 6.7 parts of BURNOCK DN-901S [polyisocyanate, manufactured by DIC Corporation]. A PET film “COSMOSHINE A4200” a surface of which is subjected to a release treatment (film thickness: 50 μm), manufactured by TOYOBO CO., LTD., was coated by bar coating with the composition-1 to a thickness of 2 μm and then prebaked at 80° C. for a minute. Subsequently, a flat-plate quartz-glass mold having a hole structure having a height of 500 nm, a width of 500 nm, and a pitch of 500 nm was pressed into the surface of the composition-1. In this state, the composition-1 was cured by being irradiated, on the resin-composition side, with light from a LED light source having a peak wavelength of 375 nm±5 at a dose of 1000 mJ/cm². After that, the mold and the PET film were released from each other to provide a shaped article having pillar-shaped surface irregularities.

### Examples 2 to 5 and Comparative Examples 1 to 3

Curable resin compositions (composition-2) to (composition-5) were prepared on the basis of formulations described in Table 1 by the same method as in Example 1. Comparative curable resin compositions (comparative composition-1) to (comparative composition-3) were prepared on the basis of formulations described in Table 2 by the same method as in Example 1. Shaped articles having pillar-shaped surface irregularities were obtained by the same method as in Example 1.

### Examples 6 to 10

### Method for Producing Shaped Article Having Surface Irregularities

PET films “HB film” (film thickness: 100 μm), manufactured by TEIJIN LIMITED, was coated by bar coating with the composition-1 to the composition-5 to a thickness of 2 μl and then prebaked at 80° C. for a minute. Subsequently, a flat-plate nickel mold having a moth-eye structure having a height of 250 nm and a pitch of 280 nm was pressed into the surfaces of the composition-1 to the composition-5. In this state, the composition-1 to the composition-5 were cured by being irradiated with light from a metal halide lamp through the PET films at a dose of 1000 mJ/cm². After that, the mold and the PET films were released from each other to provide shaped articles having moth-eye-shaped surface irregularities (FS-1 to FS-5).

### Comparative Examples 4 to 6

### Method for Producing Shaped Article Having Surface Irregularities

Shaped articles having moth-eye-shaped surface irregularities (FS-2) and (FS-4) were obtained with the comparative compositions 1 to 3 by the same method as in Examples 6 to 10.

### (Production of Substrate-Type Solar-Cell Module)

The hot plate of a laminator (manufactured by Nisshinbo Mechatronics Inc.) was adjusted to be 150° C. On the hot plate, a stainless-steel plate, the solar-cell sealing material, a polycrystalline-silicon solar cell, the solar-cell sealing material, and one of the shaped articles described in Examples 6 to 10 and Comparative examples 4 to 6 ((FS-1) to (FS-8), note that such a shaped article was placed such that the coating surface of the curable resin composition became the outermost layer) were stacked in this order; in the state where the lid of the laminator was closed, sequentially subjected to deaeration for 3 minutes and pressing for 22 minutes; and taken out of the laminator. Thus, substrate-type solar-cell modules ((M-1) to (M-8)) were provided.

### (Evaluation)

The shaped articles having surface irregularities obtained in Examples 1 to 5 and Comparative examples 1 to 3 were evaluated in the following manner.

(Evaluation of Degree of Yellowing after Accelerated Light Resistance Test)

An accelerated light resistance test was performed with an ultraviolet-deterioration accelerating tester (EYE Super UV Tester SUV-W131, manufactured by IWASAKI ELECTRIC CO., LTD.) at an UV irradiation intensity of 100 mW/cm2.

The shaped articles having pillar-shaped surface irregularities were evaluated before and after the accelerated test for 200 hours. The degree of yellowing of the shaped articles was evaluated in the following manner. The b value representing yellowness in the Lab color space was determined with a colorimeter CR-100 manufactured by Minolta Camera, Inc. When the difference Ab between b values before and after the test is 0 to 1, the degree of yellowing was evaluated as Good; when the Ab is 1 to 5, the degree of yellowing was evaluated as Fair; when the Ab is 5 or more, the degree of yellowing was evaluated as Poor.

### (Weatherability Evaluation)

The shaped articles having pillar-shaped surface irregularities were subjected to an accelerated weathering test with a sunshine weatherometer and change in the appearance between before and after the test was observed. (in compliance with JIS D 0205; black panel temperature: 63° C.; relative humidity: 50%; light irradiance: 255 W/m2; water spraying: 12 min/60 min; irradiation time: 3000 hours)

Weatherability evaluation was performed by evaluating the appearance characteristics in accordance with the following grading system.

5; no change
4; hair cracks (narrow cracks) are dispersed
3; cracks having a width of 1 mm or more are observed
2; the coating film partially becomes separated and missing
1; most of the coating film becomes missing

### (Weatherability Evaluation of Solar-Cell Protective Sheet)

The solar-cell protective sheet (FS-1) and comparative solar-cell protective sheets (FS-2) to (FS-5) were subjected to an accelerated weathering test (3000 hours) with a sunshine weatherometer and change in the appearance between before and after the test was observed. Weatherability evaluation was performed by evaluating the appearance characteristics in accordance with the above-described weatherability grading system.

### (Evaluation Method: Evaluation of Light Reflectivity)

Before and after the accelerated weathering test (3000 hours) of the solar-cell protective sheet (FS-1) and comparative solar-cell protective sheets (FS-2) to (FS-5) with a sunshine weatherometer, the reflectivity of light beams in the wavelength range of 360 nm to 740 nm was measured with a CM-3600d manufactured by Minolta Co., Ltd. The average reflectivity in the visible-light range of 500 nm to 740 nm was determined. When the variation between before and after the accelerated weathering test was less than 2%, the sheet was evaluated as Good; when the variation is 2 or more and less than 4, the sheet was evaluated as Fair; when the variation is 4 or more, the sheet was evaluated as Poor.

### (Evaluation Method: Evaluation of Diffuse Light Transmittance)

Before and after the accelerated weathering test (3000 hours) of the solar-cell protective sheet (FS-1) and comparative solar-cell protective sheets (FS-2) to (FS-5) with a sunshine weatherometer, the diffuse transmittance of light in the wavelength range of 360 nm to 740 nm was measured with a CM-3600d manufactured by Minolta Co., Ltd. The average transmittance in the visible-light range of 500 nm to 740 nm was determined. When the variation between before and after the accelerated weathering test was less than 2%, the sheet was evaluated as Good; when the variation is 2 or more and less than 5, the sheet was evaluated as Fair; when the variation is 5 or more, the sheet was evaluated as Poor.

### (Evaluation Method: Evaluation of Power Output of Solar-Cell Module)

The substrate-type solar-cell modules (M-1) to (M-5) obtained above were fixed at a horizontal angle of 50° on an exposed platform disposed outdoors in Sakura city, Chiba prefecture and left to stand for 6 months.

Values calculated by dividing the power generation efficiency of the solar-cell modules (M-1) to (M-5) after the outdoor exposure for 6 months by the power generation efficiency before the outdoor exposure was defined as a power generation efficiency ratio. When the power generation efficiency ratio is 0.95 or more, the module was evaluated as Good; when the ratio is 0.90 or more and less than 0.95, the module was evaluated as Fair; when the ratio is less than 0.90, the module was evaluated as Poor.

The composition ratios in Examples 1 to 5 and Comparative examples 1 to 3 and the evaluation results of the resultant shaped articles having pillar-shaped surface irregularities are described in Tables 1 and 2.

TABLE 1

| | | Example 1 | Example 2 | Example 3 | Example 4 | Example 5 |
|---|---|---|---|---|---|---|
| Composite resin | (A-1) | 40 | | | | |
| | (A-2) | | 21.4 | | | |
| | (A-3) | | | 10 | | |
| | (A-4) | | | | 40 | |
| | (A-5) | | | | | 38.7 |
| Comparative resin | (R-1) | | | | | |
| | (R-2) | | | | | |
| (a1) content (%) with respect to composite | | 50 | 75 | 50 | 30 | 36.2 |
| resin *3 | | | | | | |
| (a1) content (%) *1 | | 28 | 46.9 | 12.1 | 14.3 | 24 |
| Polyisocyanate | DN-901S | 6.7 | 3.1 | 1 | 9.4 | 9.3 |
| (B) content (%) *2 | | 18.7 | 13.1 | 5 | 22.6 | 16.2 |
| Polyfunctional acrylate | PETA | 7 | 4.4 | | 10 | 9.8 |
| | 17-813 | | | 16.9 | | |
| Photopolymerization | I-184 | 1.08 | 0.78 | 0.37 | 1.2 | 1.5 |
| initiator | I-127 | | | 0.37 | | |
| UV absorbing agent | TINUVIN 384 | | 0.45 | | | |
| | TINUVIN 400 | 0.67 | | | 0.79 | 0.94 |
| | TINUVIN 479 | | | 0.2 | | |
| Light stabilizer (HALS) | TINUVIN 123 | 0.34 | 0.23 | | 0.39 | 0.47 |
| | TINUVIN 152 | | | 0.2 | | |
| Composition name | | composition-1 | composition-2 | composition-3 | composition-4 | composition-5 |
| Evaluation of shaped | Degree of yellowing | Good | Good | Good | Good | Good |
| article having pillar- | Weatherability | 5 | 5 | 5 | 5 | 5 |
| shaped surface | | | | | | |
| irregularities | | | | | | |

TABLE 2

| | | Comparative | Comparative | Comparative |
|---|---|---|---|---|
| | | Example 1 | Example 2 | Example 3 |
| Composite resin | (A-1) | | | |
| | (A-2) | | | |
| | (A-3) | | | |
| | (A-4) | | | |
| | (A-5) | | | |
| Comparative resin | (R-1) | | | 30 |
| | (R-2) | 30 | 40 | |
| (a1) content (%) with respect to composite | | 70 | 70 | 0 |
| resin *3 | | | | |
| (a1) content (%) *1 | | 65.4 | 38.9 | 0 |
| Polyisocyanate | DN-901S | 0.8 | | |
| (B) content (%) *2 | | 0 | 3 | 0 |
| Polyfunctional acrylate | PETA | | 3.2 | |
| | 17-813 | | | |
| Photopolymerization | I-184 | 1.20 | 0.93 | 1.2 |
| initiator | I-127 | | | |
| UV absorbing agent | TINUVIN 384 | | | |
| | TINUVIN 400 | 0.60 | 0.48 | 0.6 |
| | TINUVIN 479 | | | |
| Light stabilizer (HALS) | TINUVIN 123 | 0.30 | 0.24 | 0.3 |
| | TINUVIN 152 | | | |
| Composition name | | comparative | comparative | comparative |
| | | composition-1 | composition-2 | composition-3 |
| Evaluation of shaped | Degree of yellowing | Good | Good | Poor |
| article having pillar- | Weatherability | 4 | 4 | 2 |
| shaped surface | | | | |
| irregularities | | | | |

The composition ratios in Examples 6 to 10 and Comparative examples 4 to 6 and the evaluation results of the resultant shaped articles having moth-eye-shaped surface irregularities are described in Tables 3 and 4.

TABLE 3

| | | Example 6 | Example 7 | Example 8 | Example 9 | Example 10 |
|---|---|---|---|---|---|---|
| Composition name | | composition-1 | composition-2 | composition-3 | composition-4 | composition-5 |
| Shaped article name | | FS-1 | FS-2 | FS-3 | FS-4 | FS-5 |
| Presence or absence of moth-eye-shaped irregularities | | Present | Present | Present | Present | Present |
| Evaluation of shaped article | Degree of yellowing | Good | Good | Good | Good | Good |
| having moth-eye-shaped | Weatherability | 5 | 5 | 5 | 5 | 5 |
| surface irregularities | | | | | | |
| Light-beam reflectivity | Initial value | 1.0 | 1.0 | 1.0 | 1.0 | 1.0 |
| | After SWOM | 1.1 | 1.0 | 1.2 | 1.3 | 1.2 |
| | Evaluation | Good | Good | Good | Good | Good |
| Diffuse light transmittance | Initial value | 93.1 | 93.0 | 92.9 | 93.1 | 93.0 |
| | After SWOM | 92.7 | 93.0 | 92.6 | 91.8 | 92.0 |
| | Evaluation | Good | Good | Good | Good | Good |
| Solar-cell module name | | M-1 | M-2 | M-3 | M-4 | M-5 |
| Power generation efficiency ratio | Power generation | 0.98 | 0.99 | 0.97 | 0.96 | 0.97 |
| | efficiency ratio | | | | | |
| | Evaluation | Good | Good | Good | Good | Good |

TABLE 4

| | | Comparative | Comparative | Comparative |
|---|---|---|---|---|
| | | example 4 | example 5 | example 6 |
| Composition name | | comparative | comparative | comparative |
| | | composition-1 | composition-2 | composition-3 |
| Shaped article name | | FS-6 | FS-7 | FS-8 |
| Presence or absence of moth-eye-shaped | | Present | Present | Present |
| irregularities | | | | |
| Evaluation of shaped | Degree of | Good | Good | Poor |
| article having moth-eye- | yellowing | | | |
| shaped surface | Weatherability | 4 | 4 | 2 |
| irregularities | | | | |
| Light-beam reflectivity | Initial value | 1.0 | 1.0 | 1.0 |
| | After SWOM | 4.7 | 3.1 | 5.2 |
| | Evaluation | Poor | Fair | Poor |
| Diffuse light transmittance | Initial value | 93.0 | 93.0 | 93.0 |
| | After SWOM | 86.6 | 89.0 | 82.0 |
| | Evaluation | Poor | Fair | Poor |
| Solar-cell module name | | M-6 | M-7 | M-8 |
| Power generation | Power generation | 0.88 | 0.94 | 0.80 |
| efficiency ratio | efficiency ratio | | | |
| | Evaluation | Poor | Fair | Poor |

Regarding abbreviations in Tables 1 to 4:
(a1) is the abbreviation of the polysiloxane segment (a1)
*1: content (%) of the polysiloxane segment (a1) with respect to the total solids weight of the curable resin composition
*2: content (%) of the polyisocyanate (B) with respect to the total solids weight of the curable resin composition
*3: content of the polysiloxane segment (a1) with respect to the total solids weight of the composite resin (A)
DN-901S: BURNOCK DN-901S [polyisocyanate, manufactured by DIC Corporation]
17-813: UNIDIC 17-813 [urethane acrylate, manufactured by DIC Corporation]
PETA: pentaerythritol triacrylate
I-184: IRGACURE 184 [photopolymerization initiator, manufactured by Ciba Japan K. K.]
I-127: IRGACURE 127 [photopolymerization initiator, manufactured by Ciba Japan K. K.]
TINUVIN 479: [hydroxyphenyl triazine-based UV absorbing agent, manufactured by Ciba Japan K. K.]
TINUVIN 152: [hindered amine-based light stabilizer (HALS), manufactured by Ciba Japan K. K.]

### INDUSTRIAL APPLICABILITY

A shaped article having irregularities according to the present invention is suitably usable as a surface protective member for a light-receiving surface of a solar-cell module. In addition, the shaped article is also usable in various applications including mold films, nano/micro optical components, optical elements, display elements, electronic papers, storages, MEMS/PCB packaging materials, high-performance three-dimensional nano/micro channels intended for microbiochemistry analysis, microchemistry synthesis, and biological applications, next-generation electronic elements, and DNA chips.

### REFERENCE SIGNS LIST

1: solar-cell protective sheet for light-receiving surface
2: first sealing material
3: solar-cell group
4: second sealing material
5: solar-cell protective sheet for back surface

1. A shaped article having surface irregularities, comprising a fine structure including projections and a recess formed between the projections, the fine structure being formed in part of or in entirety of a surface of the shaped article formed by curing a curable resin composition, the fine structure having a depth in a range of 0.01 to 50 μm and, in at least one direction, a pitch in a range of 0.01 to 50 μm,
wherein the curable resin composition contains a composite resin (A) in which a polysiloxane segment (a1) having a structural unit represented by a general formula (1) and/or a general formula (2) and a silanol group and/or a hydrolyzable silyl group is bonded to a vinyl-based polymer segment (a2) having an alcoholic hydroxy group through a bond represented by a general formula (3), and polyisocyanate (B); a content of the polysiloxane segment (a1) with respect to total solids weight of the curable resin composition is 10% to 60% by weight; and a content of the polyisocyanate (B) with respect to total solids weight of the curable resin composition is 5% to 50% by weight 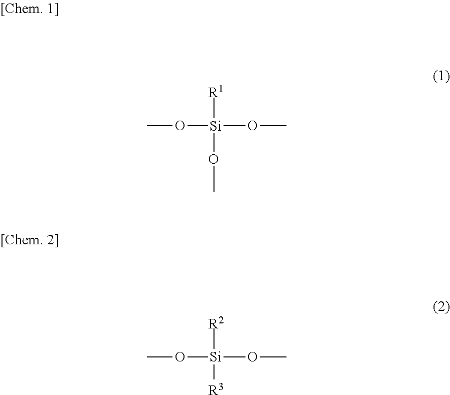
(in the general formulae (1) and (2), R¹, R², and R³ each independently represent a group having one polymerizable double bond and selected from the group consisting of —R⁴—CH═CH₂, —R⁴—C(CH₃)═CH₂, —R⁴—O—CO—C(CH₃)═CH₂, and —R⁴—O—CO—CH═CH₂ (where R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms; and at least one of R¹, R², and R³ represents the group having a polymerizable double bond) 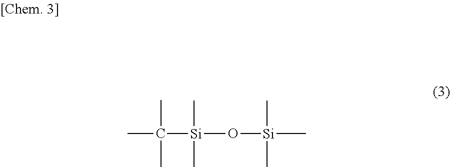
(in the general formula (3), the carbon atom constitutes a part of the vinyl-based polymer segment (a2), and the silicon atom that is bonded to the oxygen atom only constitutes a part of the polysiloxane segment (a1)).

2. The shaped article having surface irregularities according to claim 1, wherein the shaped article is formed by curing a curable-resin-composition layer disposed on a surface of a base.

3. The shaped article having surface irregularities according to claim 2, wherein the base is a sheet-shaped base.

4. A surface protective member for a light-receiving surface of a solar-cell module, comprising the shaped article according to claim 3.

5. A solar-cell module comprising the surface protective member for a light-receiving surface of a solar-cell module according to claim 4.

6. A method for producing the shaped article having surface irregularities according to claim 1, the method comprising pressing a mold having an irregular structure into a curable-resin-composition layer disposed on a surface of a base; in this state, curing the curable-resin-composition layer by an active energy ray applied on a curable-resin-composition side; and subsequently releasing the mold.

7. A method for producing the shaped article having surface irregularities according to claim 2, the method comprising pressing a mold having an irregular structure into a curable-resin-composition layer disposed on a surface of a base; in this state, curing the curable-resin-composition layer by an active energy ray applied on a curable-resin-composition side; and subsequently releasing the mold.

8. A method for producing the shaped article having surface irregularities according to claim 3, the method comprising pressing a mold having an irregular structure into a curable-resin-composition layer disposed on a surface of a base; in this state, curing the curable-resin-composition layer by an active energy ray applied on a curable-resin-composition side; and subsequently releasing the mold.
